(19) United States
(12) Patent Application Publication
(10) Pub. No.: US 2011/0096219 A1
(43) Pub. Date: Apr. 28, 2011

(54) IMAGE SENSOR PACKAGE AND METHOD FOR MANUFACTURING THE SAME

(75) Inventors: Pen-Jung Lee, Sindian City (TW); Yu-Te Hsieh, Sindian City (TW); Chiung-Kun Chuang, Sindian City (TW); Ling-Ta Su, Sindian City (TW); Ming-Chieh Lin, Sindian City (TW)

(73) Assignee: Celsia Technologies Taiwan, Inc.

(21) Appl. No.: 12/795,837

(22) Filed: Jun. 8, 2010

(30) Foreign Application Priority Data
Oct. 28, 2009 (TW) 098136483

(51) Int. Cl. H04N 5/335; H01L 31/18

(52) U.S. Cl. 348/308; 438/65; 257/E31.127

(57) ABSTRACT

An image sensor package includes a substrate, an image sensor chip, a plurality of metal wires and an encapsulant. The substrate has an upper face, a lower face and a plurality of connecting pads arranged on the upper face. The image sensor chip has an active surface, a back surface opposite to the active surface and a plurality of bonding pads arranged on the active surface. The metal wires electrically connect the bonding pads of the image sensor chip to the connecting pads of the substrate. The transparent cover is arranged above the image sensor chip. A gap is formed between the transparent cover and the image sensor chip. The encapsulant is disposed around the transparent cover and the metal wires, and is used for sealing the metal wires and fixing the transparent cover above the image sensor chip.

### BACKGROUND OF THE INVENTION

1. Field of the Invention

The present invention generally relates to an image sensor package, in particular to an image sensor package whose transparent cover with supporting wall is placed in manufacturing process by pick-up heads.

2. Description of Prior Art

As the world enters into the digital era, the applications and developments of the digital video equipments such as digital cameras or digital camcorders have got more and more attention. On the other hand, the development of the semiconductor technology also provides possibilities of integrating the digital video equipments into various kinds of consumer electronic products such as mobile phone, personal digital assistant (PDA), etc. Such development also increases the market demand of the abovementioned consumer electronic products.

These digital video equipments have core devices of image sensor packages, which can be assembled with other devices like signal processing unit, storage unit and outputting unit to form a representative product of the digital era. The image sensor package is a semiconductor component which is able to transform optical images into electric signals, and it has main applications like digital camera and other video equipments.

Since the developing trends of the camera phone are toward high definition, high image quality, multi-function and compact size, thus the image sensor package therein emphasizes on reducing the package size of it. In another aspect, new manufacturing technology such as chip scale packaging can package the image sensor chip with other optical components into an image sensor package which has its size close to the size of the chip itself. However, in order to meet the requirement of reducing size of such portable electronic devices, product makers have to continuously develop image sensor packages having smaller size and thinner thickness. Therefore, how to modify the image sensor package to have more compact size of it while not reducing its mechanical strength and original function has become one of the main subjects in this industry.

U.S. Pat. No. 6,995,462 discloses an image sensor package whose transparent cover is bonded over the image sensitive chip with an adhesive material. The adhesive material can be an epoxy, a silicone, an acrylic or other liquid-type adhesive. However, such liquid-type adhesive is easily to flow on the transparent cover, the shape and the thickness of the adhesive can not be controlled precisely. Thus the image sensor chip and the transparent cover are hard to be aligned parallel to each other, the optical performance is consequently worse than the original design. Hence it seems that the adhesion method mentioned above needs further improving to solve the problem.

### SUMMARY OF THE INVENTION

Therefore, it is a primary objective of the present invention to provide an image sensor package, which has thinner thickness and can be used for the present portable electronic devices.

It is a secondary objective of the present invention to provide method of manufacturing the image sensor package mentioned above.

To achieve the foregoing objective, the present invention discloses an image sensor package including a substrate, an image sensor chip, a plurality of metal wires and an encapsulant. The substrate has an upper face, a lower face and a plurality of connecting pads arranged on the upper face. The substrate can be made of bismaleimide-triazine resin, glass-fiber-reinforced plastic layer, printed circuit board, high temperature printed circuit board, polyimide film or ceramic circuit board.

The image sensor chip has an active surface, a back surface opposite to the active surface and a plurality of bonding pads arranged on the active surface. The image sensor chip is arranged on the upper face of the substrate. The image sensor chip can be a CCD chip or a CMOS chip.

The metal wires electrically connect the bonding pads of the image sensor chip to the connecting pads of the substrate. The metal wires can be gold wires, aluminum wires, silver wires or tin wires.

The transparent cover is arranged above the image sensor chip. A gap is formed between the transparent cover and the image sensor chip. The transparent cover can be infra-red filter, anti-reflection coating glass, optical low-pass filter, bare glass or transparent plastics.

The encapsulant is disposed around the transparent cover and the metal wires, and is used for sealing the metal wires and fixing the transparent cover above the image sensor chip.

In addition, a method of manufacturing image sensor package is also disclosed. The method includes the following steps: providing a substrate; arranging a plurality of image sensor chips on the substrate; providing a plurality of metal wires electrically connected the image sensor chips to the substrate; positioning a plurality of transparent covers above the image sensor chips respectively, a plurality of gaps formed between each of the transparent covers and the corresponding image sensor chips; disposing encapsulant around the transparent covers and the metal wires, the encapsulant sealing the metal wires and fixing the transparent covers above the image sensor chips; and dicing the substrate to obtain a plurality of image sensor packages, each of the image sensor packages having one image sensor chip.

Since the peripheral wall supports the transparent cover above the image sensor chip. The thickness of the peripheral wall 402 can be small. The total thickness of the image sensor package can be decreased to satisfy the requirements of the compact portable electronic devices.

### BRIEF DESCRIPTION OF THE DRAWINGS

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1A is a schematic view of an image sensor package of the present invention.

FIG. 1B is a schematic view of another image sensor package of the present invention.

FIG. 2 shows a perspective view of the transparent cover.

FIG. 3 depicts the manufacture of the transparent cover.

FIG. 4 shows a sectional view of the image sensor package of the present invention.

FIG. 5 shows a flow chart of method of manufacturing image sensor package of the present invention.

FIG. 6A to FIG. 6G are sectional views corresponding to the steps in FIG. 5.

### DETAILED DESCRIPTION OF THE INVENTION

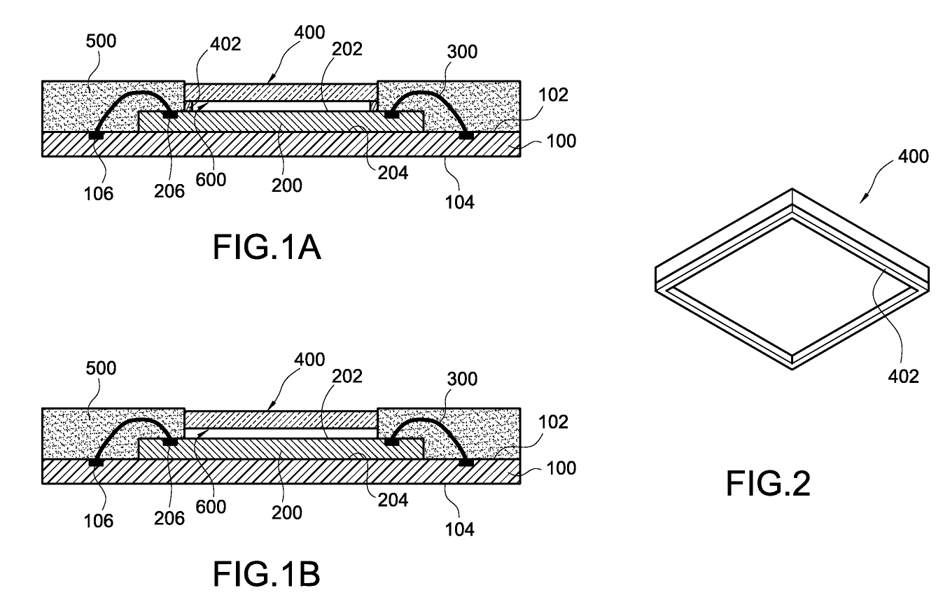

FIG. 1A is a schematic view of an image sensor package of the present invention. The image sensor package includes a substrate 100, an image sensor chip 200, a plurality of metal wires 300, a transparent cover 400 and an encapsulant 500.

The substrate 100 has an upper face 102, a lower face 104 and a plurality of connecting pads 106 arranged on the upper face 102. These connecting pads 106 are further connected to a plurality of connecting pads (not shown) on the lower face 104. The substrate 100 is made of bismaleimide-triazine resin, glass-fiber-reinforced plastic layer, printed circuit board, high temperature printed circuit board, polyimide film or ceramic circuit board.

The image sensor chip 200 has an active surface 202, a back surface 204 opposite to the active surface 202 and a plurality of bonding pads 206 arranged on the active surface 202. The image sensor chip 200 is arranged on the upper face 102 of the substrate 100 and the back surface 204 is attached to the upper face 102. The image sensor chip 200 can be a CCD chip or a CMOS chip.

The metal wires 300 are electrically connected the bonding pads 206 of the image sensor chip 200 to the connecting pads 106 of the substrate 100. External electrical power can be feed into the image sensor chip 200 through the metal wires 300 when operating. The metal wires 300 can be gold wires, aluminum wires, silver wires or tin wires.

The transparent cover 400 is arranged above the image sensor chip 200 in parallel. A gap 600 is formed between the transparent cover 400 and the image sensor chip 200. The transparent cover 400 can be infra-red filter, anti-reflection coating glass, optical low-pass filter, bare glass or transparent plastics. The transparent cover 400 should be able to filter out IR light and to pass light of wavelength between 400 nm˜650 nm.

In addition, as FIG. 1A and FIG. 2 show, a peripheral wall 402 can be further disposed on the lower face of the transparent cover 400. The peripheral wall 402 is used for supporting the transparent cover 400 above the image sensor chip 200. The area surrounded by the peripheral wall 402 should be larger than the active sensing area of the image sensor chip 200. The peripheral wall 402 can be made of positive photo resist or negative photo resist by lithography process. The photo resist can be SU8, PI or black matrix resin. In practical use, the photo resist can be a dry film photo resist. It should be noticed that, after the lithography process, the photo resist should be baked to remove all the solvent in the photo resist to obtain the peripheral wall 402 with a solid thickness. The baking process also makes the peripheral wall 402 non-adhesive. Besides, the lithography process provides the peripheral wall 402 with a uniform thickness. Since the thickness of the peripheral wall 402 is solid and uniform, the image sensor chip 200 and the transparent cover 400 are able to be aligned parallel to each other, and the optical performance will be close to the original design. Since the transparent cover 400 is supported by the peripheral wall 402, the gap 600 is formed between the transparent cover 400 and the image sensor chip 200. It should be mentioned that the peripheral wall 402 can be neglected in practical manufacturing, as FIG. 1B shows.

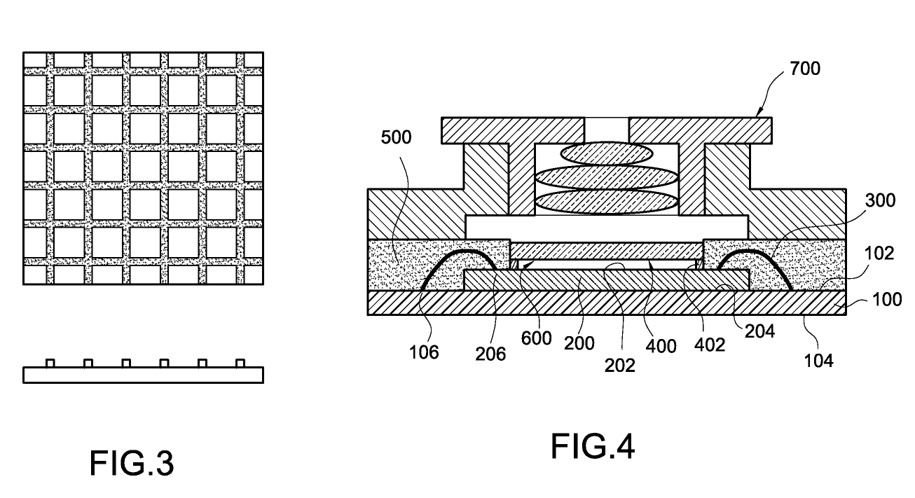

The peripheral wall 402 can be manufactured by lithography process on a singular transparent cover 400. Or, for the purpose of mass production, as FIG. 3 shows, a grid-like rib can be disposed on the transparent substrate by lithography process, then the transparent substrate can be singularized into a plurality of transparent covers 400 with peripheral walls 402.

The encapsulant 500 is disposed in liquid form around the transparent cover 400 and the metal wires 300, after the encapsulant 500 is solidified, it can be used for sealing the metal wires 300 and fixing the transparent cover 400 above the image sensor chip 200.

Because contaminations or particles are easily attached on the transparent cover 400 in the process of manufacturing, the gap 600 between the transparent cover 400 and the image sensor chip 200 can effectively prevent the contaminations or particles on the transparent cover 400 from forming images on the image sensor chip 200. Besides, the gap 600 can also prevent the image sensor chip 200 from scratching by the transparent cover 400.

Since the encapsulant 500 is disposed after the transparent cover 400 is positioned above the image sensor chip 200, the encapsulant 500 will not be squeezed into the active sensing area of the image sensor chip 200 by the transparent cover 400 as the conventional method. In addition, the peripheral walls 402 can also be used for blocking the liquid encapsulant 500 from reaching the active sensing area of the image sensor chip 200.

In addition, the gap 600 can provide an air medium for the image sensor package of the present invention. Light beam incident into the interface between the transparent cover 400 and the gap 600 can be refracted and focused on the image sensor chip 200, which makes the image quality captured by the image sensor chip better.

Further, as FIG. 4 shows, the image sensor package can be integrated into an image sensor module with a lens barrel 700 having a plurality of lens therein. The image sensor module includes the image sensor package of the present invention and the lens barrel 700. The lens barrel 700 is disposed on the image sensor package. The image sensor package can capture the exterior image by the lens in the lens barrel 700.

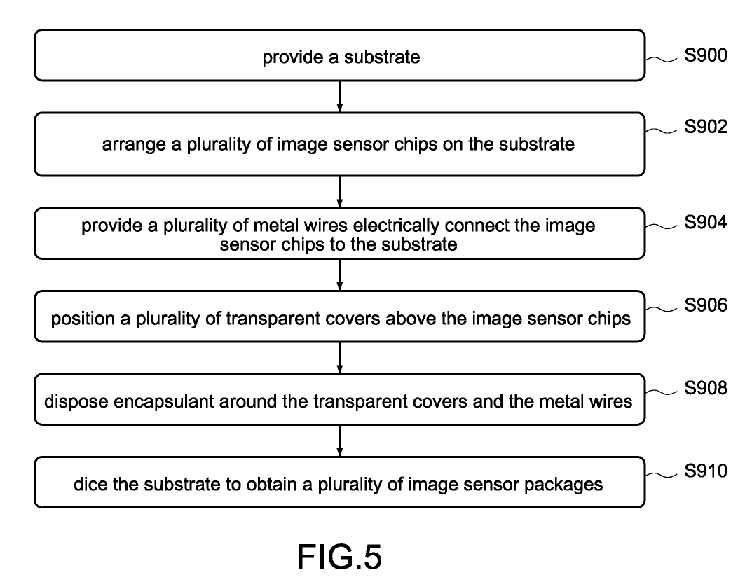

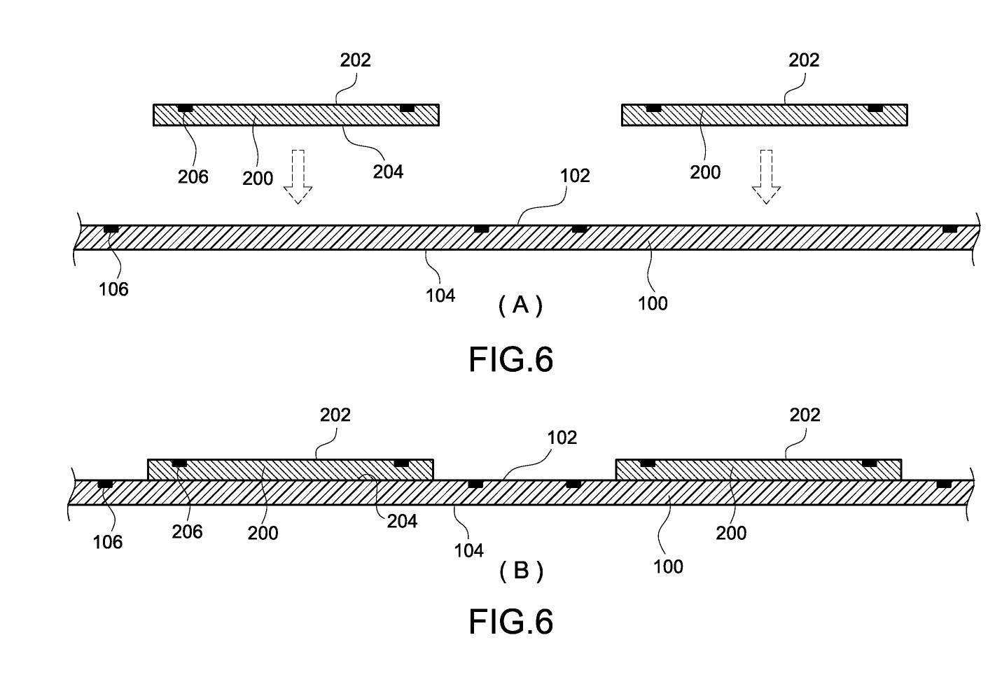

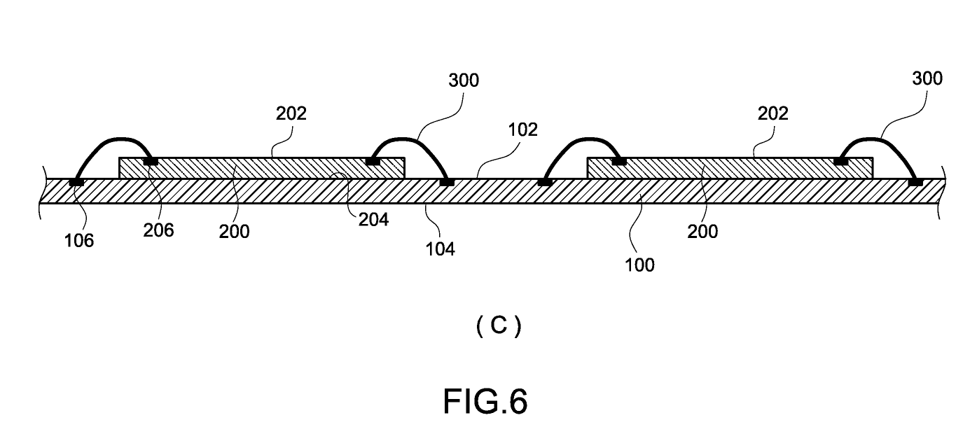

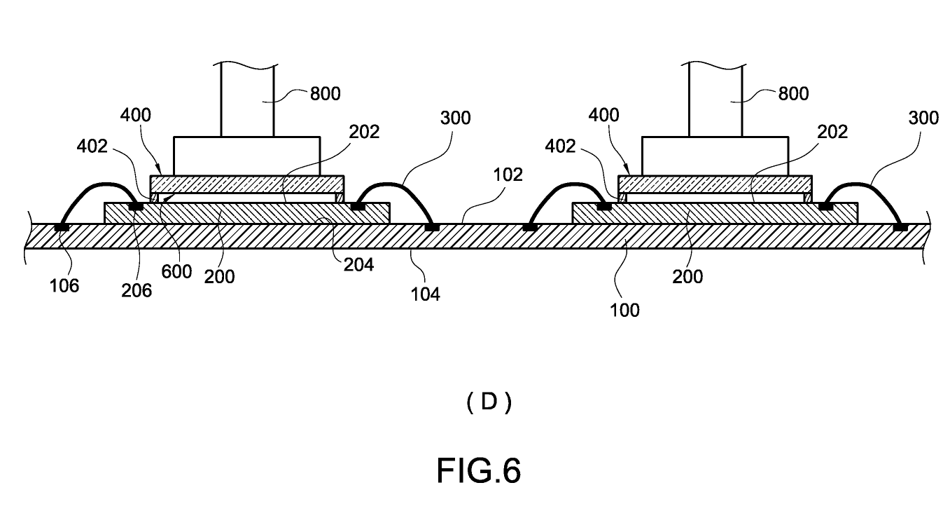

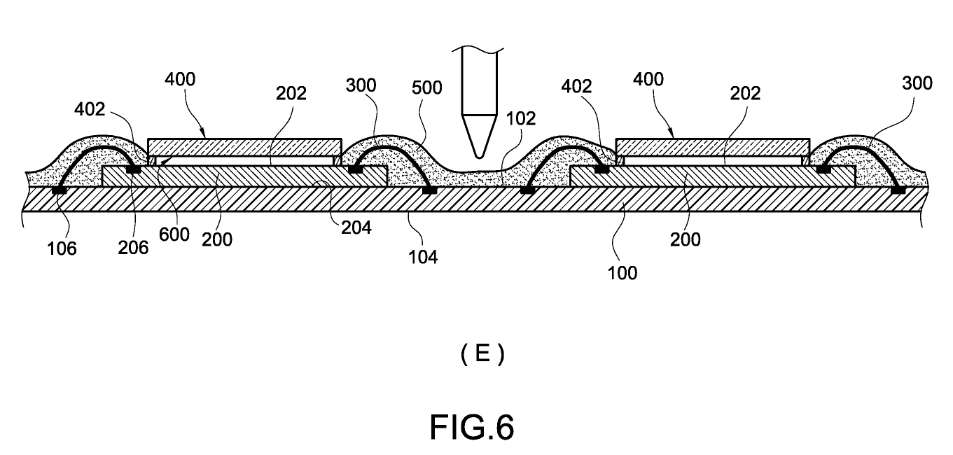

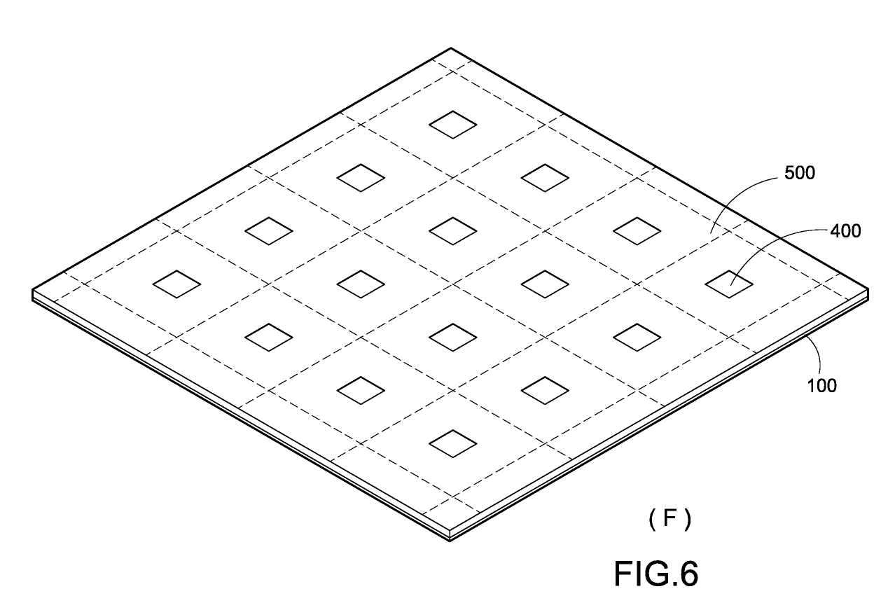

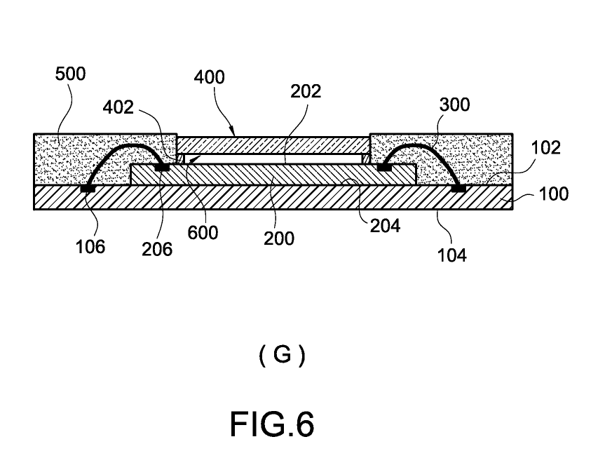

FIG. 5 shows a flow chart of method of manufacturing image sensor package of the present invention. In step S900, as FIG. 6A shows, a substrate 100 is provided. The substrate 100 has an upper face 102, a lower face 104 and a plurality of connecting pads 106 arranged on the upper face 102.

In step S902, as FIG. 6B shows, a plurality of image sensor chips are arranged on the substrate 100. Each of the image sensor chips 200 includes has an active surface 202, a back surface 204 opposite to the active surface 202 and a plurality of bonding pads 206 arranged on the active surface 202. The image sensor chip 200 is arranged on the upper face 102 of the substrate 100 and the back surface 204 is attached to the upper face 102.

In step S904, as FIG. 6C shows, a plurality of metal wires 300 are provided to electrically connect the bonding pads 206 of the image sensor chip 200 to the connecting pads 106 of the substrate 100. External electrical power can be fed into the image sensor chip 200 through the metal wires 300 when operating.

In step S906, a plurality of transparent covers 400 are respectively positioned above the image sensor chips 200 by pick-up heads 800. Each of the transparent covers 400 has a peripheral wall 402 thereon. The pick-up head 800 attaches the transparent cover 400 on the face opposite to the peripheral wall 402, and places the peripheral wall 402 of the transparent cover 400 on the image sensor chip 200. In practical manufacturing, the peripheral wall 402 can be neglected. The transparent covers 400 can be positioned above the image sensor chips 200 only by pick-up heads 800 and not with the supporting of the peripheral wall 402. The pick-up heads 800 can hold the transparent covers 400 until the next step (S908) is finished.

In step S908, as FIG. 6E shows, the encapsulant 500 in liquid form is disposed around the transparent covers 400 and the metal wires 300. It can be used for sealing the metal wires 300 and fixing the transparent cover 400 above the image sensor chip 200. The encapsulant 500 is formed by single shot dispensing or continuous multiple shot dispensing.

After the encapsulant 500 is solidified, a plurality of image sensor package are formed on the upper face 102 of the substrate 100 as FIG. 6F shows. Finally, in step S910, the substrate 100 is diced to obtain a plurality of image sensor packages. Each of the image sensor packages has one image sensor chip 200.

In addition, the manufacturing of image sensor package of the present invention can be chose to proceed in vacuum environment, which is able to avoid air bubble remaining inside the encapsulant 500 and particles attaching on the image sensor chip 200. Thus the yield of production can be improved. Besides, heat treatment can be applied on the lower face 104 of the substrate 100 to reflow the encapsulant 500, thus more uniform distribution of the encapsulant 500 can be obtained.

Accordingly, the peripheral wall 402 supports the transparent cover 400 above the image sensor chip 200. Since the thickness of the peripheral wall 402 is small, the total thickness of the image sensor package can be decreased to satisfy the requirements of the compact portable electronic devices. In addition, positioning the transparent cover 400 above the image sensor chip 200 by the pick-up head 800 simplifies the manufacturing of the image sensor package. The yield of the production is also increased.

While the invention has been described by means of specific embodiments, numerous modifications and variations could be made thereto by those skilled in the art without departing from the scope and spirit of the invention set forth in the claims.

What is claimed is:

1. An image sensor package, comprises:
a substrate having an upper face, a lower face and a plurality of connecting pads arranged on the upper face;
an image sensor chip having an active surface, a back surface opposite to the active surface and a plurality of bonding pads arranged on the active surface, wherein the image sensor chip is arranged on the upper face of the substrate;
a plurality of metal wires electrically connected the bonding pads of the image sensor chip to the connecting pads of the substrate;
a transparent cover arranged above the image sensor chip wherein a gap is formed between the transparent cover and the image sensor chip; and
an encapsulant disposed around the transparent cover and the metal wires and sealing the metal wires and fixing the transparent cover above the image sensor chip.

2. The image sensor package of claim 1, wherein the substrate is made of bismaleimide-triazine resin, glass-fiber-reinforced plastic layer, printed circuit board, high temperature printed circuit board, polyimide film or ceramic circuit board.

3. The image sensor package of claim 1, wherein the image sensor chip is a CCD chip or a CMOS chip.

4. The image sensor package of claim 1, wherein the transparent cover has a peripheral wall thereon, wherein the peripheral wall supports the transparent cover above the image sensor chip.

5. The image sensor package of claim 4, wherein the peripheral wall is made of positive photo resist or negative photo resist by lithography process, and the photo resist is baked to remove all the solvent therein.

6. The image sensor package of claim 1, wherein the transparent cover is infra-red filter, anti-reflection coating glass, optical low-pass filter, bare glass or transparent plastics.

7. The image sensor package of claim 1, wherein the metal wires are gold wires, aluminum wires, silver wires or tin wires.

8. A method of manufacturing image sensor package, comprises:
providing a substrate;
arranging a plurality of image sensor chips on the substrate;
providing a plurality of metal wires electrically connected the image sensor chips to the substrate;
positioning a plurality of transparent covers above the image sensor chips respectively, a plurality of gaps formed between each of the transparent covers and the corresponding image sensor chips;
disposing encapsulant around the transparent covers and the metal wires, the encapsulant sealing the metal wires and fixing the transparent covers above the image sensor chips; and
dicing the substrate to obtain a plurality of image sensor packages, each of the image sensor packages having one image sensor chip.

9. The method of claim 8, wherein the substrate is made of bismaleimide-triazine resin, glass-fiber-reinforced plastic layer, printed circuit board, high temperature printed circuit board, polyimide film or ceramic circuit board.

10. The method of claim 8, wherein the image sensor chips are CCD chips or CMOS chips.

11. The method of claim 8, wherein a plurality of peripheral walls are disposed on the transparent covers respectively and the peripheral walls are used for supporting the transparent covers above the image sensor chips.

12. The method of claim 11, wherein the peripheral walls are made of positive photo resist or negative photo resist by lithography process, and the photo resist is baked to remove all the solvent therein.

13. The method of claim 8, wherein the transparent covers are infra-red filters, anti-reflection coating glasses, optical low-pass filters, bare glasses or transparent plastics.

14. The method of claim 8, wherein the metal wires are gold wires, aluminum wires, silver wires or tin wires.

15. The method of claim 8, wherein the encapsulant is formed by single shot dispensing or continuous multiple shot dispensing.

16. An image sensor package, comprises:
a substrate having a upper face, a lower face and a plurality of connecting pads arranged on the upper face;
an image sensor chip having an active surface, a back surface opposite to the active surface and a plurality of bonding pads arranged on the active surface, wherein the image sensor chip is arranged on the upper face of the substrate;
a plurality of metal wires electrically connected the bonding pads of the image sensor chip to the connecting pads of the substrate;
a transparent cover having a peripheral wall thereon, the peripheral wall supporting the transparent cover above the image sensor chip and being made of positive photo resist or negative photo resist by lithography process, and the photo resist baked to remove all the solvent therein; and
an encapsulant disposed around the transparent cover and the metal wires and sealing the metal wires and fixing the transparent cover above the image sensor chip.

17. The image sensor package of claim 16, wherein the substrate is made of bismaleimide-triazine resin, glass-fiber-reinforced plastic layer, printed circuit board, high temperature printed circuit board, polyimide film or ceramic circuit board.

18. The image sensor package of claim 16, wherein the image sensor chip is a CCD chip or a CMOS chip.

19. The image sensor package of claim 16, wherein the transparent cover is infra-red filter, anti-reflection coating glass, optical low-pass filter, bare glass or transparent plastics.

20. The image sensor package of claim 16, wherein the metal wires are gold wires, aluminum wires, silver wires or tin wires.
